(19) United States
(12) Patent Application Publication
(10) Pub. No.: US 2008/0203444 A1
(43) Pub. Date: Aug. 28, 2008

(54) Multi-finger transistor and method of manufacturing the same

(75) Inventors: Han-Su Kim, Seoul (KR); Je-Don Kim, Seoul (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/071,339

(22) Filed: Feb. 20, 2008

(30) Foreign Application Priority Data
Feb. 27, 2007 (KR) 10-2007-0019395

(51) Int. Cl. H01L 29/808; H01L 21/337

(52) U.S. Cl. 257/270; 438/195; 257/E29.312; 257/E21.445

(57) ABSTRACT

A multi-finger transistor and method of manufacturing the same are provided. The multi-finger transistor includes two active regions, a multi-finger gate, a plurality of source regions and a plurality of drain regions. The two active regions are defined in a unit cell of a substrate. The multi-finger gate includes a plurality of gate fingers formed in the two active regions and a gate connector between the two active regions. The gate connector connects the gate fingers to each other. The source regions are formed in first portions of the two active regions adjacent to the gate fingers. The drain regions are formed in second portions of the two active regions adjacent to the gate fingers.

### PRIORITY STATEMENT

This application claims the benefit of priority under 35 USC §119 to Korean Patent Application No. 2007-19395, filed on Feb. 27, 2007 in the Korean Intellectual Property Office (KIPO), the contents of which are herein incorporated by reference in their entirety.

### BACKGROUND

1. Field

Example embodiments relate to a multi-finger transistor and a method of manufacturing the same. Other example embodiments provide a multi-finger transistor having a decreased area and increased performance and a method of manufacturing the same.

2. Description of the Related Art

In order to increase a maximum oscillation frequency of a metal-oxide-semiconductor (MOS) transistor in an input/output circuit or a radio-frequency (RF) circuit, a multi-finger gate having a plurality of gate fingers is generally more useful than a single-finger gate. A transistor including a multi-finger gate is referred to as a multi-finger transistor.

FIGS. 1A to 1C are diagrams illustrating top views of conventional multi-finger transistors.

Referring to FIG. 1A, a multi-finger transistor 100 has a unit cell defined (or provided) by a guard ring 140 formed on a substrate 110. An active region 120 and a field region 130 are defined in the unit cell. A plurality of gate fingers 152 may be formed in the active region 120. The gate fingers 152 may be electrically connected to each other via a gate connector 154. The gate fingers 152 together with the gate connector 154 may be referred to as a multi-finger gate 150. A plurality of source regions 160 and a plurality of drain regions 170 may be formed in portions of the active region 120 adjacent to the gate fingers 152.

A first plug 155 electrically connects the multi-finger gate 150 to a first wiring (not shown). The source regions 160 may be electrically connected to a second wiring (not shown) via a second plug (not shown). The drain regions 170 may be electrically connected to a third wiring (not shown) via a third plug (not shown). A fourth plug 145 electrically connects the guard ring 140 to a fourth wiring (not shown).

Referring to FIGS. 1B and 1C, multi-finger transistors 200 and 300 are substantially the same as the multi-finger transistor 100 in FIG. 1A except for the inclusion of gate connectors 254 and 354 and first plugs 255 and 355, respectively. According to the types of the gate connectors 154, 254 and 354, the multi-finger transistors 100, 200 and 300 may be referred to as a meander transistor, a comb transistor and a folded transistor, respectively.

The gate connector 154 in FIG. 1A connects the gate fingers 152 to each other in series, the gate connector 254 in FIG. 1B connects gate fingers 252 on one side of an active region 220 to each other, and the gate connector 354 in FIG. 1C connects gate fingers 352 on both sides of an active region 320 to each other.

The folded transistor 300 in FIG. 1C has a gate resistance one-half of the meander transistor in FIG. 1A or one-fourth of the comb transistor in FIG. 1B. As such, the folded transistor 300 has a relatively higher maximum oscillation frequency. The folded transistor 300 may have a higher parasitic capacitance. The folded transistor 300 may have a parasitic capacitance higher than that of the meander transistor 100 or the comb transistor 200 wherein the parasitic capacitance of the folded transistor 300 is generated between a guard ring 340 and a first wiring (not shown) electrically connected to the gate connector 354 via a first plug 355. A portion of the first wiring of the folded transistor 300 adjacent to the guard ring 340 has an area twice as large as that of a portion of a first wiring of the comb transistor 200 adjacent to a guard ring 240. The portion of the first wiring of the folded transistor 300 adjacent to the guard ring 340 has an area at least twice as large as that of a portion of the first wiring of the meander transistor 100 adjacent to the guard ring 140. As such, the folded transistor 300 has a higher parasitic capacitance.

A cut-off frequency is inversely proportional to a parasitic capacitance such that the cut-off frequency decreases if the parasitic capacitance increases. As such, the folded transistor 300 may have degenerating characteristics. The parasitic capacitance may decrease as the distance between the multi-finger gate 350 and the guard ring 340 increases. The folded transistor may have an increased area.

### SUMMARY

Example embodiments relate to a multi-finger transistor and a method of manufacturing the same. Other example embodiments provide a multi-finger transistor having a decreased area and/or increased performance and a method of manufacturing the same.

Example embodiments provide a multi-finger transistor having a decreased area, lower gate resistance and/or lower parasitic capacitance.

According to example embodiments, there is provided a multi-finger transistor. The multi-finger transistor includes at least two active regions, a multi-finger gate, a plurality of source regions and a plurality of drain regions. The two active regions are defined (or established) in a unit cell of a substrate. The multi-finger gate includes a plurality of gate fingers formed in the active regions and a gate connector formed between the two active regions. The gate connector connects the gate fingers to each other. The source regions may be formed in a first portion of the active regions adjacent to the gate fingers. The drain regions may be formed in a second portion of the active regions adjacent to the gate fingers.

In example embodiments, each of the gate fingers may extend in a first direction. The gate connector may extend in a second direction substantially perpendicular to the first direction.

In example embodiments, each of the source and drain regions may extend in the first direction. The source and drain regions may be alternately formed (or disposed) in the second direction.

In example embodiments, the multi-finger transistor may include a first wiring electrically connected to the multi-finger gate, a second wiring electrically connected to the source regions and a third wiring electrically connected to the drain regions.

In example embodiments, the first and fourth wirings may have substantially the same height from the substrate. In example embodiments, the second and third wirings may have substantially the same height from the substrate. The second and third wirings may be formed opposite to each other.

In example embodiments, the unit cell may be defined (or established) by a guard ring doped with impurities. The multi-finger transistor may include a fourth wiring electrically connected to the guard ring. In example embodiments, the source and drain regions may include n-type impurities and the guard ring includes p-type impurities.

In example embodiments, the second and fourth wirings may be grounded. An input/output signal may be applied to the third wiring.

In example embodiments, the first, second, third and fourth wirings may include a metal. In other example embodiments, the third wiring may include a metal substantially the same as that of the second wiring. The first wiring may include a metal different from that of the second wiring.

In example embodiments, the multi-finger gate, the source regions, the drain regions and the guard ring may be electrically connected to the first, second, third and fourth wirings via first, second, third and fourth plugs, respectively. The multi-finger gate may include polysilicon or the like.

In example embodiments, the two active regions may have substantially the same area.

Example embodiments also provide a method of manufacturing a multi-finger transistor including providing a unit cell of a substrate having two active regions, forming a multi-finger gate including a plurality of gate fingers in the two active regions and a gate connector between the two active regions. The gate connector connects the gate fingers to each other.

The method includes forming a plurality of source drains in first portions of the two active regions adjacent to the plurality of gate fingers, and forming a plurality of drain regions in second portions of the two active regions adjacent to the plurality of gate fingers.

According to example embodiments, the two active regions are formed in a unit cell defined (or provided) by a guard ring. A gate connector may be formed between the active regions. The distance between the guard ring and a wiring formed over the gate connector may be increased such that a multi-finger transistor including the unit cell has a decreased parasitic capacitance and/or a higher cut-off frequency.

According to example embodiments, one wiring at most may be formed at (or in) a central portion of the unit cell such that the multi-finger transistor may have a decreased gate resistance and/or a higher maximum oscillation frequency.

### BRIEF DESCRIPTION OF THE DRAWINGS

Example embodiments will be more clearly understood from the following detailed description taken in conjunction with the accompanying drawings. FIGS. 1-4 represent non-limiting, example embodiments as described herein.

FIGS. 1A to 1C are diagrams illustrating top views of conventional multi-finger transistors;

FIG. 2 is a diagram illustrating top view of a multi-finger transistor according to example embodiments;

FIGS. 3A to 3D are diagrams illustrating cross-sectional views of the multi-finger transistor shown in FIG. 2 taken along lines I-I′, II-II′, III-III′ and IV-IV′, respectively; and

FIG. 4 is a diagram illustrating a top view of a conventional multi-finger transistor used as a comparative example.

### DETAILED DESCRIPTION OF EXAMPLE EMBODIMENTS

Various example embodiments will now be described more fully with reference to the accompanying drawings in which some example embodiments are shown. In the drawings, the thicknesses of layers and regions may be exaggerated for clarity.

Detailed illustrative embodiments are disclosed herein. However, specific structural and functional details disclosed herein are merely representative for purposes of describing example embodiments. This invention may, however, may be embodied in many alternate forms and should not be construed as limited to only example embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but on the contrary, example embodiments are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the scope of example embodiments.

Spatially relative terms, such as “beneath,” “below,” “lower,” “above,” “upper” and the like, may be used herein for ease of description to describe one element or a relationship between a feature and another element or feature as illustrated in the figures. It will be understood that the spatially relative terms are intended to encompass different orientations of the device in use or operation in addition to the orientation depicted in the Figures. For example, if the device in the figures is turned over, elements described as “below” or “beneath” other elements or features would then be oriented “above” the other elements or features. Thus, for example, the term “below” can encompass both an orientation which is above as well as below. The device may be otherwise oriented (rotated 90 degrees or viewed or referenced at other orientations) and the spatially relative descriptors used herein should be interpreted accordingly.

Example embodiments are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

In order to more specifically describe example embodiments, various aspects will be described in detail with reference to the attached drawings. However, the present invention is not limited to example embodiments described.

Example embodiments relate to a multi-finger transistor and a method of manufacturing the same. Other example embodiments provide a multi-finger transistor having a decreased area and/or increased performance and a method of manufacturing the same.

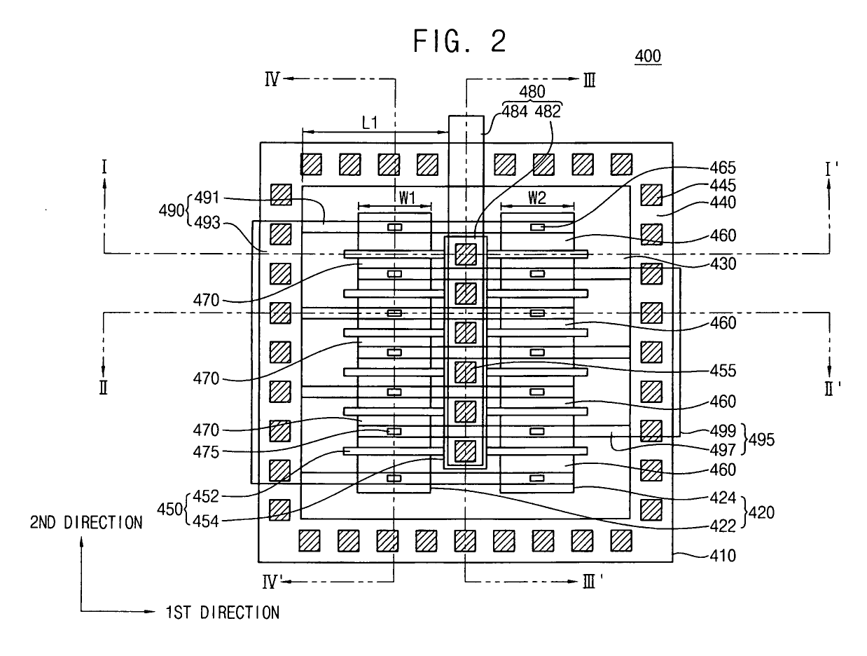

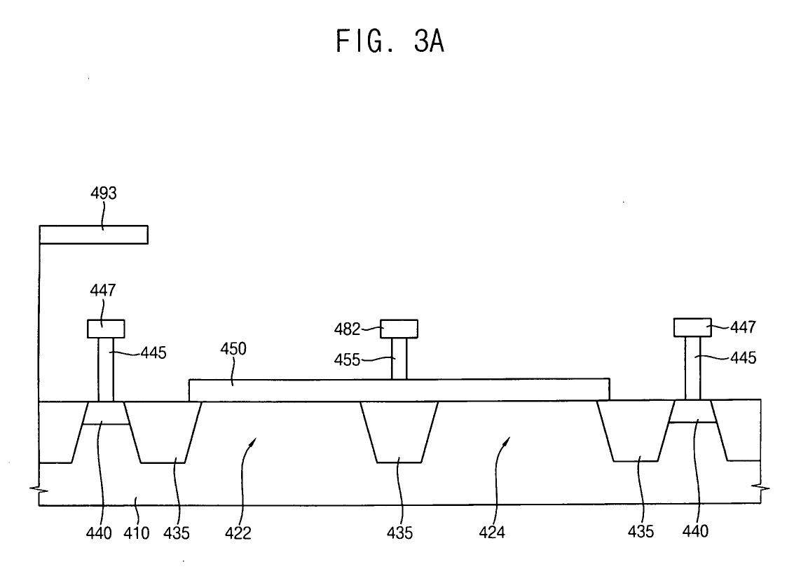

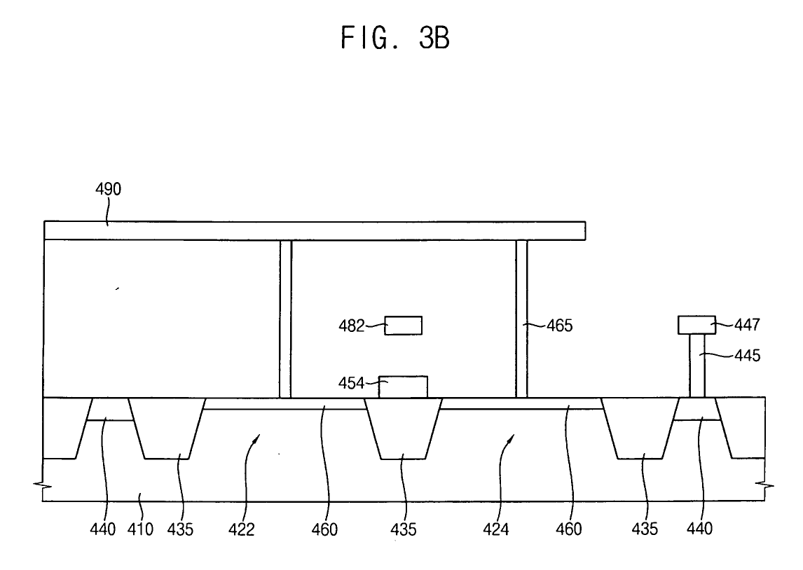

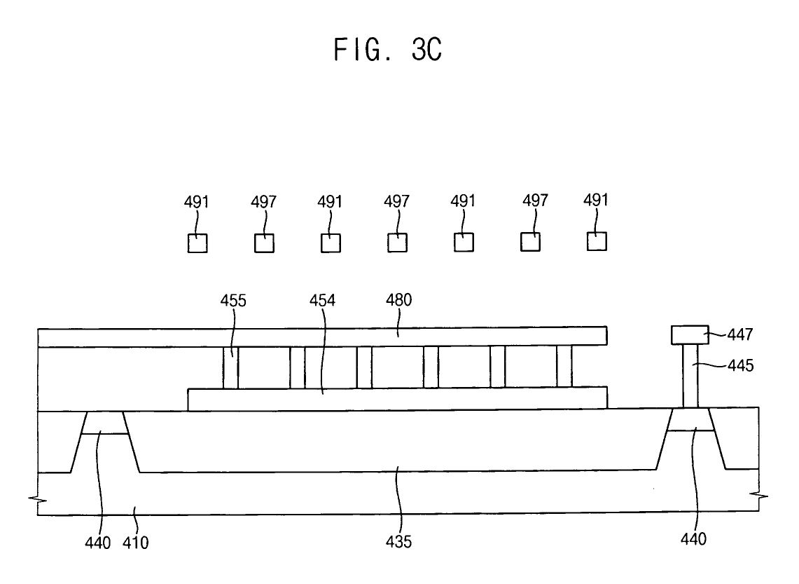

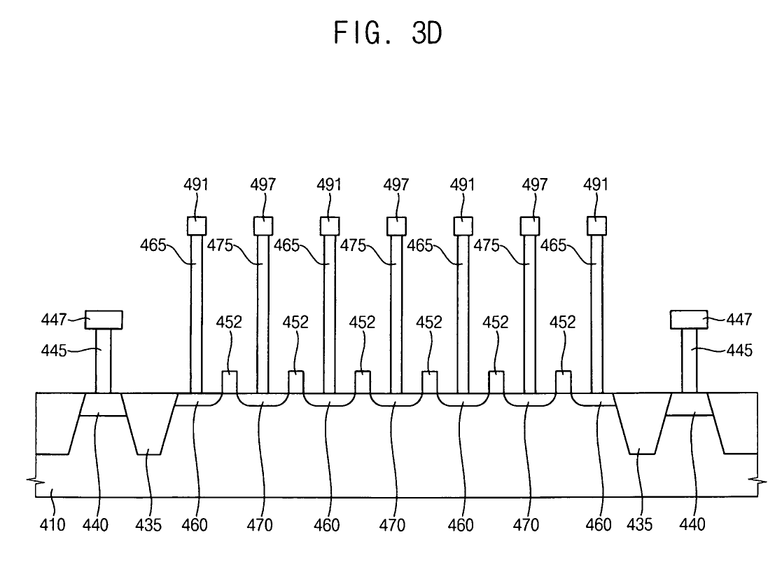

FIG. 2 is a diagram illustrating a top view of a multi-finger transistor according to example embodiments. FIGS. 3A to 3D are diagrams illustrating cross-sectional views of the multi-finger transistor in FIG. 2 taken along lines I-I′, II-II′, III-III′ and IV-IV′, respectively. A fourth wiring is not shown in FIG. 2A and insulating interlayers formed between respective layers are not shown in FIGS. 3A to 3D for the simplicity of the drawings.

Referring to FIGS. 2 and 3A to 3D, a multi-finger transistor 400 has a plurality of unit cells (only one unit cell is shown in FIG. 2). The unit cells may be defined by a guard ring 440. The multi-finger transistor 400 has an active region 420 including a first active region 422 and a second active region 424. The active region 420 may be distinguished from a field region 430 defined by an isolation layer 435. The isolation layer 435 may include an oxide.

A substrate 410 may include silicon, germanium or combinations thereof. A p-type well (not shown) in which p-type impurities are doped, or an n-type well (not shown) in which n-type impurities are doped, may be formed in an upper portion of the substrate 410. If the p-type well is formed in an upper portion of the substrate 410, the guard ring 440 having a p+ diffusion region may provide a bias voltage to the p-type well.

In example embodiments, the first and second active regions 422 and 424 have substantially the same shape and surface area. Alternatively, the first and second active regions 422 and 424 may have different shapes and/or surface areas. The first active region 422 may have a first width W₁ different from a second width W₂ of the second active region 424.

A plurality of gate fingers 452 may be formed in the active region 420. In example embodiments, each of the gate fingers 452 extends in a first direction such that the gate fingers 452 are parallel to each other.

The gate fingers 452 may be connected to each other via a gate connector 454. The gate connector 454 may be formed between the first and second active regions 422 and 424 such that the distance between the guard ring 440 and the gate connector 454 in the multi-finger transistor 400 may be higher than that of the conventional multi-finger transistor. As such, the distance L1 between the guard ring 440 and a first wiring 480 formed over the gate connector 454 increases, decreasing the parasitic capacitance of the multi-finger transistor 400.

In example embodiments, the gate connector 454 extends in a second direction substantially perpendicular to the first direction.

The gate fingers 452 and the gate connector 454 may include polysilicon. The gate fingers 452 and the gate connector 454 may include a metal.

A source region 460 and a drain region 470 may be formed at portions of the active region 420. A plurality of source regions 460 and a plurality of drain regions 470 may be alternately formed between portions of the active region 420 covered by the gate fingers 452. In example embodiments, each of the source and drain regions 460 and 470 extends in the first direction. If the substrate 410 has a p-type well, the source and drain regions 460 and 470 may be n+ diffusion regions in which n-type impurities are doped.

The gate connector 454 may be electrically connected to the first wiring 480 via a first plug 455. The first plug may include a conductive material.

The first wiring 480 includes a first connection portion 482 and an extension portion 484. The first connection portion 482 may be directly connected to the gate connector 454 via the first plug 455. The extension portion 484 extends from the first connection portion 482. An external signal is applied to the extension portion 484. The first plug 455 may be formed through a first insulating interlayer (not shown). The first wiring 480 may be formed on the first insulating interlayer. The first wiring 480 may include a conductive material (e.g., a metal).

The guard ring 440 may be electrically connected to a fourth wiring 447 via a fourth plug 445. The fourth plug 445 may include a conductive material.

The fourth wiring 447 may be grounded. The fourth wiring 447 include a conductive material (e.g., a metal). The fourth plug 445 may be formed through the first insulating interlayer. The fourth wiring 447 may be formed on the first insulating interlayer.

The source region 460 may be electrically connected to a second wiring 490 via a second plug 465. The second plug 465 may include a conductive material.

The second wiring 490 includes a plurality of second connection portions 491 and a first conjunction portion 493. The second connection portions 491 may be directly connected to the plurality of source regions 460, respectively. The first conjunction portion 493 connects the plurality of the second connection portions 491 to each other. The second wiring 490 may be grounded. The second plug 465 may be formed through a second insulating interlayer, which is formed on the first insulating interlayer. The second wiring 490 may be formed on the second insulating interlayer. The second wiring 490 may include a conductive material (e.g., a metal).

A third wiring 495 includes a plurality of third connection portions 497 and a second conjunction portion 499. The third connection portions 497 may be directly connected to the plurality of drain regions 470, respectively, via a third plug 475. The second conjunction portion 499 connects the plurality of the third connection portions 497 to each other. An input/output signal may be applied to the third wiring 495. In example embodiments, the third plug 475 may be formed through the first and second insulating interlayers. The third wirings 495 may be formed on the second insulating interlayer.

Each of the second and third connection portions 491 and 497 may extend in the first direction. The second and third connection portions 491 and 497 may be alternately disposed in the second direction. Each of the first and second conjunction portions 493 and 499 may extend in the second direction. The first and second conjunction portions 493 and 499 may be opposite to each other.

The third wiring 495 may include a conductive material (e.g., a metal). In example embodiments, the second and third wirings 490 and 495 include substantially the same metal and a metal different from that of the first wiring 480.

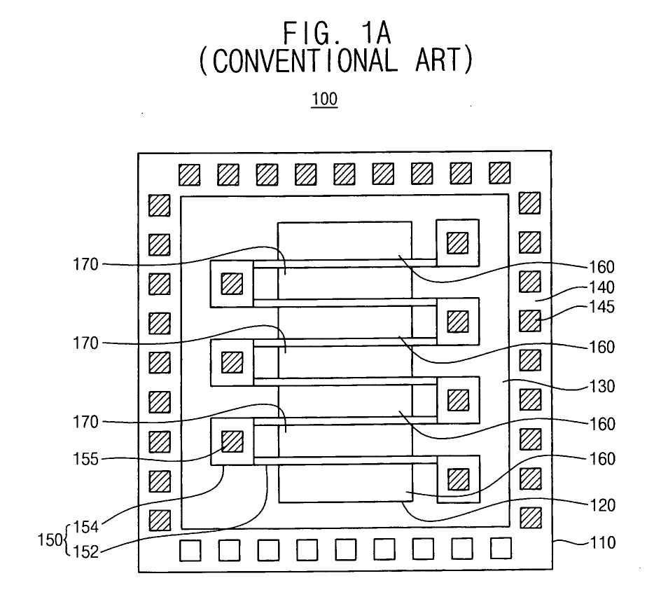

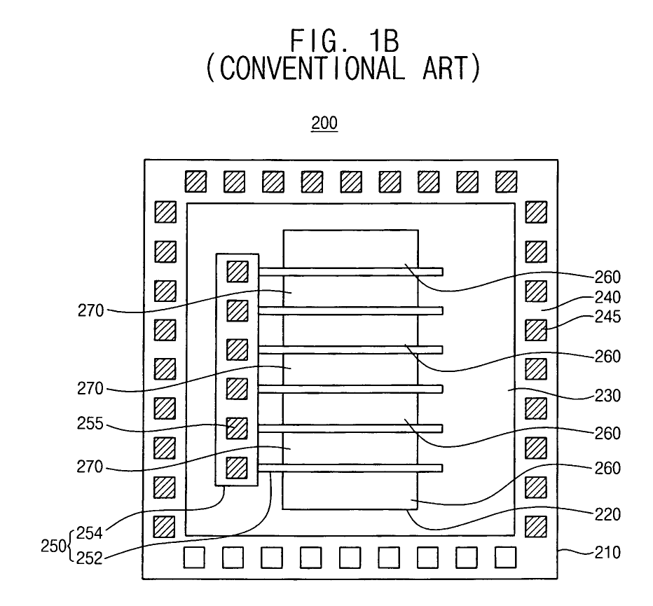

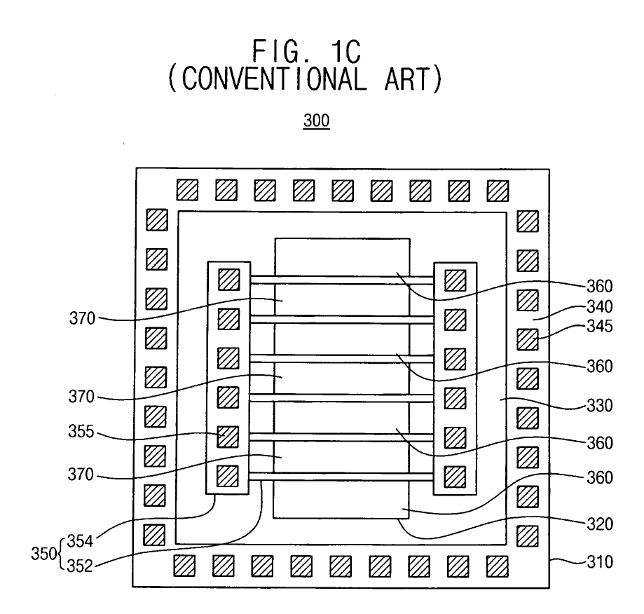

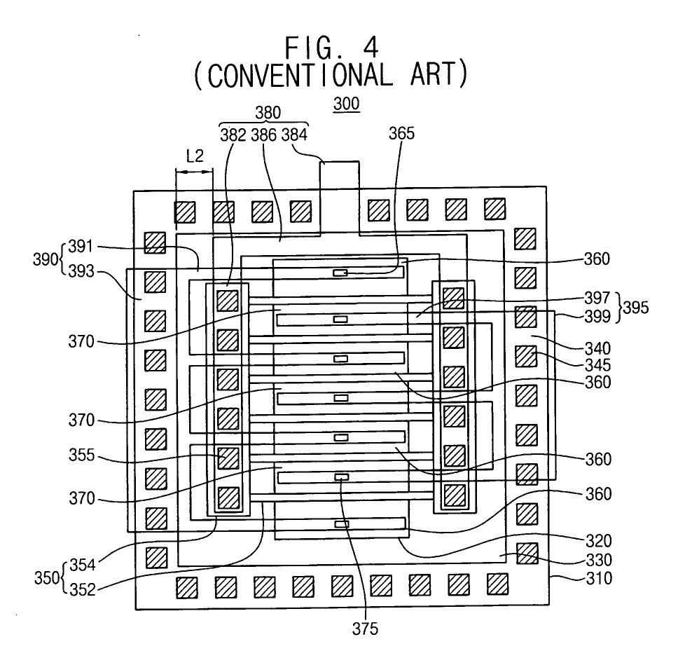

FIG. 4 is a diagram illustrating a top view of a conventional multi-finger transistor used as a comparative example. The multi-finger transistor is a folded transistor described in the related art and is substantially the same as the multi-finger transistor 300 in FIG. 1C, except first to third wirings are shown in FIG. 4. Thus, the reference numeral 300 is used to describe the multi-finger transistor in FIG. 4.

Referring to FIG. 4, the gate connector 354 may be formed on both sides of the active region 320. A first wiring 380 may be formed over the gate connector 354 and electrically connected to the gate connector 354 via the first plug 355. The distance L2 between the guard ring 340 and the first wiring 380 may be smaller than the distance L1 between the guard ring 440 and the first wiring 480 in the multi-finger transistor 400 shown in FIG. 2. As such, the multi-finger transistor 400 according to example embodiments has a parasitic capacitance lower than that of the multi-finger transistor 300. The multi-finger transistor 400 has a relatively higher cut-off frequency than that of the multi-finger transistor 300.

Because the multi-finger transistor 400 according to example embodiments exhibits a lower parasitic capacitance lower than that of the multi-finger transistor 300, assuming that the two multi-finger transistors 400 and 300 had substantially the same parasitic capacitance, the multi-finger transistor 400 may be formed having a smaller unit cell area than that of the multi-finger transistor 300.

In the multi-finger transistor 300 in FIG. 4, the first wiring 380 includes a first connection portion 382, an extension portion 384 and a bridge portion 386. The first connection portion 382 may be directly connected to the gate connector 354 via the first plug 355. The extension portion 384 extends from the first connection portion 382. An external signal is applied to the extension portion 384. The bridge portion 386 connects the first connection portion 382 and the extension portion 384. A gate resistance of the multi-finger transistor 300 increases as the length of the bridge portion 386 increases. The multi-finger transistor 400 may have a gate resistance smaller than that of the multi-finger transistor 300. The multi-finger transistor 400 may have a relatively higher maximum oscillation frequency than that of the multi-finger transistor 300.

According to example embodiments, two active regions may be formed in a unit cell defined by a guard ring. A gate connector may be formed between the active regions. The distance between the guard ring and a wiring formed over the gate connector is increased such that a multi-finger transistor including the unit cell exhibits decreased parasitic capacitance and/or a higher cut-off frequency.

According to example embodiments, one wiring at most is formed at a central portion of the unit cell such that the multi-finger transistor exhibits decreased gate resistance and/or a higher maximum oscillation frequency.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages. Accordingly, all such modifications are intended to be included within the scope of this invention as defined in the claims. In the claims, means-plus-function clauses are intended to cover the structures described herein as performing the recited function, and not only structural equivalents but also equivalent structures. Therefore, it is to be understood that the foregoing is illustrative of various example embodiments and is not to be construed as limited to the specific embodiments disclosed, and that modifications to the disclosed embodiments, as well as other embodiments, are intended to be included within the scope of the appended claims.

What is claimed is:

1. A multi-finger transistor, comprising:
a unit cell of a substrate, the unit cell having two active regions;
a multi-finger gate including a plurality of gate fingers in the two active regions and a gate connector between the two active regions, wherein the gate connector connects the plurality of gate fingers to each other;
a plurality of source regions in first portions of the two active regions adjacent to the plurality of gate fingers; and
a plurality of drain regions in second portions of the two active regions adjacent to the plurality of gate fingers.

2. The multi-finger transistor of claim 1, wherein each of the plurality of gate fingers extends in a first direction, and the gate connector extends in a second direction substantially perpendicular to the first direction.

3. The multi-finger transistor of claim 2, wherein each of the plurality of source regions and each of the plurality of drain regions extends in the first direction, and the plurality of source regions and the plurality of drain regions are alternately formed in the second direction.

4. The multi-finger transistor of claim 1, further comprising:
a first wiring electrically connected to the multi-finger gate;
a second wiring electrically connected to the plurality of source regions; and
a third wiring electrically connected to the plurality drain regions.

5. The multi-finger transistor of claim 4, wherein the second and third wirings have substantially the same height from the substrate and are opposite to each other.

6. The multi-finger transistor of claim 4, further comprising a fourth wiring electrically connected to a guard ring doped with impurities, wherein the unit cell is defined by the guard ring.

7. The multi-finger transistor of claim 6, wherein the first and fourth wirings have substantially the same height from the substrate.

8. The multi-finger transistor of claim 6, wherein the plurality of source regions and the plurality of drain regions include n-type impurities, and the guard ring includes p-type impurities.

9. The multi-finger transistor of claim 6, wherein the second and fourth wirings are grounded, and an input/output signal is applied to the third wiring.

10. The multi-finger transistor of claim 6, wherein the first, second, third and fourth wirings include a metal.

11. The multi-finger transistor of claim 10, wherein the third wiring includes a metal substantially the same as that of the second wiring, and the first wiring includes a metal different from that of the second wiring.

12. The multi-finger transistor of claim 6, wherein the multi-finger gate, the source regions, the drain regions and the guard ring are electrically connected to the first to fourth wirings via first, second, third and fourth plugs, respectively.

13. The multi-finger transistor of claim 1, wherein the multi-finger gate includes polysilicon.

14. The multi-finger transistor of claim 1, wherein the two active regions have substantially the same surface area.

15. A method of manufacturing a multi-finger transistor, comprising:
providing a unit cell of a substrate, the unit cell having two active regions;
forming a multi-finger gate including a plurality of gate fingers in the two active regions and a gate connector between the two active regions, wherein the gate connector connects the plurality of gate fingers to each other;
forming a plurality of source drains in first portions of the two active regions adjacent to the plurality of gate fingers; and
forming a plurality of drain regions in second portions of the two active regions adjacent to the plurality of gate fingers.

16. The method of claim 15, wherein each of the plurality of gate fingers extends in a first direction, and the gate connector extends in a second direction substantially perpendicular to the first direction.

17. The method of claim 16, wherein each of the plurality of source regions and each of the plurality of drain regions extends in the first direction, and the plurality of source regions and the plurality of drain regions are alternately formed in the second direction.

18. The method of claim 15, further comprising:
electrically connecting a first wiring to the multi-finger gate;
electrically connecting a second wiring to the plurality of source regions; and
electrically connecting a third wiring to the plurality of drain regions.

19. The method of claim 18, wherein the second and third wirings have substantially the same height from the substrate and are opposite to each other.

20. The method of claim 15, further comprising electrically connecting a fourth wiring to a guard ring doped with impurities, wherein the unit cell is defined by the guard ring.

21. The method of claim 20, wherein plurality of source regions and the plurality of drain regions include n-type impurities, and the guard ring includes p-type impurities.

22. The method of claim 20, further comprising grounding the second and fourth wirings, and applying an input/output signal to the third wiring.

23. The method of claim 20, further comprising electrically connecting the multi-finger gate, the plurality of source regions, the plurality of drain regions and the guard ring to the first, second, third and fourth wirings, respectively.
